(19) United States
(12) Patent Application Publication
(10) Pub. No.: US 2016/0233660 A1
(43) Pub. Date: Aug. 11, 2016

(54) GFCI RECEPTACLE

(71) Applicant: Woodhead Industries, Inc., Lincolnshire, IL (US)

(72) Inventor: Paul SNAGEL, Chicago, IL (US)

(73) Assignee: Woodhead Industries, Inc., Lincolnshire, IL (US)

(21) Appl. No.: 15/015,533

(22) Filed: Feb. 4, 2016

Related U.S. Application Data
(60) Provisional application No. 62/112,983, filed on Feb. 6, 2015.

(51) Int. Cl. H02H 3/16; H05K 5/06

(52) U.S. Cl. CPC H02H 3/16; H05K 5/06

(57) ABSTRACT

A GFCI receptacle assembly includes a housing having a junction box and a cover. The housing includes a cavity with a connection insert communicating with an opening in the housing configured to connect to a plug. An electrical assembly connected to the connection insert providing fault protection and a user interface remotely positioned to the electrical assembly and having a circuit assembly to control the electrical assembly.

### RELATED APPLICATIONS

This application claims priority to U.S. Provisional Application No. 62/112983, filed on Feb. 6, 2015 which is incorporated herein by reference in its entirety.

### FIELD OF THE INVENTION

The current disclosure is directed to the field of ground fault circuit interrupters (GFCIs) and more particularly GFCIs to protect electrical devices where there are normally erratic current leakages to ground.

### DESCRIPTION OF RELATED ART

Many electrical wiring devices have a line side, which is connectable to an electrical power supply, and a load side, which is connectable to one or more loads and at least one conductive path between the line and load sides. Electrical connections to wires supplying electrical power or wires conducting electricity to the one or more loads are at line side and load side connections. The electrical wiring device industry has witnessed an increasing call for circuit breaking devices or systems which are designed to interrupt power to various loads, such as household appliances, consumer electrical products and branch circuits.

In particular, electrical codes require electrical circuits in home bathrooms and kitchens to be equipped with ground fault circuit interrupters (GFCI), for example. Presently available GFCI devices use an electrically activated trip mechanism to mechanically break an electrical connection between the line side and the load side. Such devices are resettable after they are tripped by, for example, the detection of a ground fault. A test button is used to test the trip mechanism and circuitry used to sense faults, and a reset button is used to reset the electrical connection between line and load sides. In these cases, the test button and the reset button are located on the GFCI receptacle itself, generally positioned between each socket receptacle.

In certain instances, it is required to have the GFCI's located in harsh environments with exposure to natural elements such as rain, snow and other extreme weather conditions. In these cases it is necessary to contain the GFCI receptacle in a completely watertight compartment or junction box. In addition to being housed in a watertight box it is also required to have the connection portion between the plug and each individual socket of the GFCI also to be water resistant. With current GFCI receptacle configurations, especially with the test and reset buttons located between the sockets, this can be difficult and certain individuals can appreciate the need for a structure that provides a cost effective solution to this problem.

### BRIEF SUMMARY

According to the disclosure an embodiment of a GFCI receptacle is provided that includes a pair of electrical sockets, a power interrupter, a watertight compartment and a remotely placed user interface including a keypad and display panel.

The GFCI includes a compartment having a front face and a cover body operatively joined together and housing a pair of electrical sockets for connection to a typical three pronged plug. The front face includes a pair of openings having respective socket covers that are rotateably mounted and providing access to the sockets. A control board is disposed in the front face and electrically connected to the sockets and includes a sensing circuit for detecting a ground fault or arc fault with an integrated trip switch for interrupting the power supplied to the sockets in case of a fault.

The control board further includes a wire bundle removeably secured to the board and routed to the user interface which is mounted to the exterior of the front face and in the embodiment shown the user interface is secured to the top surface of the front face. The keypad and display panel are combined and include the test and reset buttons for operation of the GFCI and also includes a series of indicators that provide a key to the mode of failure or cause of the interruption if the GFCI has been tripped. A watertight gasket is positioned within the front face and includes glands that extend into socket openings for sealing the connection between respective plugs and sockets and a lip that seals the periphery between the front face and the body cover. The wire bundle is routed within the compartment and extends through a wall in the front face or cover body that connects the user interface to the control board. A watertight seal is also positioned between the user interface and the front face therefore providing a completely sealed and self-contained GFCI receptacle.

### BRIEF DESCRIPTION OF THE DRAWINGS

The present invention is illustrated by way of example and not limited in the accompanying figures in which like reference numerals indicate similar elements and in which:

FIG. 1 is a perspective view of the GFCI receptacle assembly;

FIG. 2 is a partial exploded view of the GFCI receptacle assembly of FIG. 1;

FIG. 3 is an exploded view of the GFCI receptacle assembly of FIG. 1;

FIG. 4 is an alternate perspective view of the GFCI receptacle assembly with the junction box removed;

FIG. 5 is a partial exploded view of the GFCI receptacle assembly of FIG. 4; and

FIG. 6 is an alternative exploded view of the GFCI receptacle assembly of FIG. 1.

### DETAILED DESCRIPTION

The appended figures illustrate an embodiment of a ground fault circuit interrupter (GFCI) receptacle assembly 20 and it is to be understood that the embodiment described and illustrated is merely exemplary of the disclosure, which may be embodied in different forms. Therefore, specific details disclosed herein are not to be interpreted as limiting, but merely as a basis for the claims and as a representative basis for teaching one skilled in the art to variously employ the present disclosure.

One or more embodiments of the disclosure utilize a modular construction and are typically used in the construction of residential and commercial building wiring. A typical residential or commercial wiring power distribution has a 120/240 volt system that includes three wire conductors, two line conductors, a neutral conductor and an earthing or reference path. The typical AC distribution system includes two line voltages that are 180 degrees out of phase so that when a voltage is measured across, a peak voltage of 240 volts is achieved and voltages across a single line conductor and a neutral is 120 volts. The embodiment described and illustrated herein is generally directed to a single-phase, polarized-receptacles and outlets.

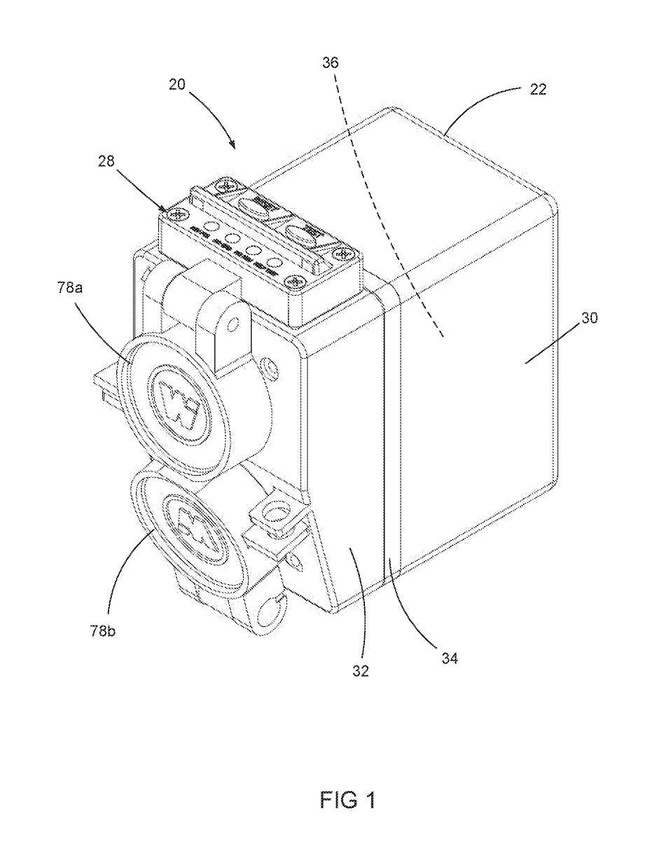

As best shown in FIG. 1 the GFCI receptacle assembly 20 includes a housing 22, a GFCI receptacle 24, a wire cover 26, and a user interface assembly 28 which are all operatively associated to one another.

The housing 22 includes a junction box 30, a cover 32, and a sealing member 34, which are all operatively associated to one another to provide a cavity 36 within the housing 22.

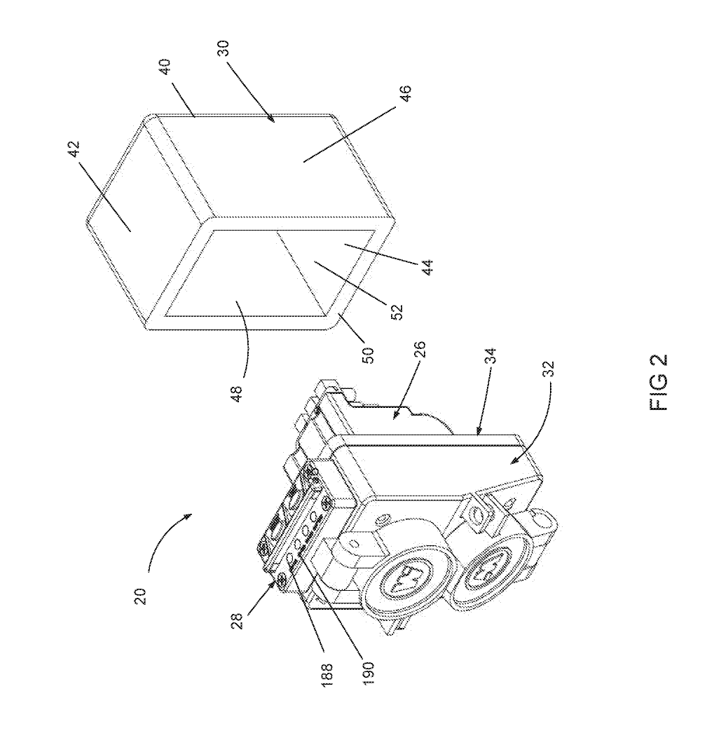

The junction box 30 includes a rear wall 40, a top wall 42, a bottom wall 44, a first side wall 46, and a second side wall 48. Each of the walls 42, 44, 46, 48 extend forward from the rear wall 40 in a generally perpendicular manner such that a front face 50 of the junction box 30 is defined by the free ends of the walls 42, 44, 46, 48 as best illustrated in FIG. 2. The walls 40, 42, 44, 46, 48 also define an open cavity of the junction box 30 therebetween. The junction box 30 further includes a conduit connection (not shown) provided through the bottom wall 44 such that conduit 54 can be in communication with the open cavity 52.

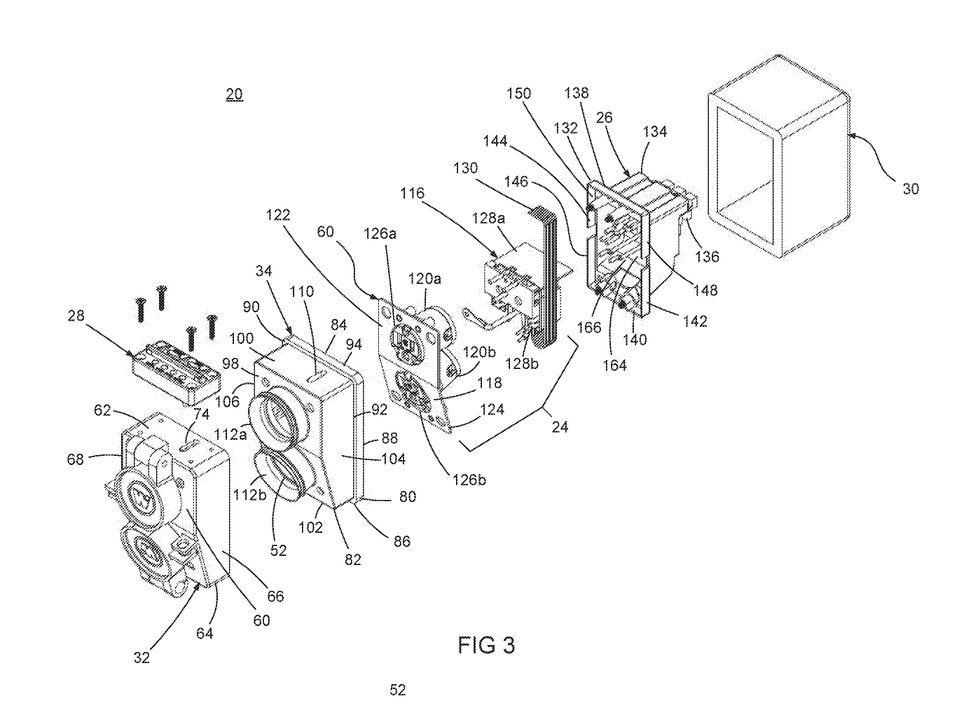

As depicted in FIG. 3 the cover 32 includes a front wall 60, a top wall 62, a bottom wall 64, a first side wall 66, and a second side wall 68. Each of the walls 62, 64, 66, 68 extend rearward from the front wall 60 in a generally perpendicular manner such that a rear face 70 of the cover 32 is defined by the free ends of the walls 62, 64, 66, 68. The walls 60, 62, 64, 66, 68 also define an open cavity 72 of the cover 32 therebetween. The top wall 62 further includes an aperture 74 provided therethrough which is in communication with the open cavity 72. The front wall 60 further includes a pair of ports 76a, 76b extending forwardly therefrom and which are in communication with the open cavity 72. Port 76a is positioned above port 76b. The cover 32 further includes a pair of port covers 78a, 78b which are configured to close off and cover the ports 76a, 76b, respectively. Port cover 78a is preferably rotatably connected to one or both of the front wall 60 and the top wall 62, such that the port cover 78a can close off and cover the port 76a, and such that the port cover 78a can allow a plug to access to the port 76a. Similarly, port cover 78b is preferably rotatably connected to one or both of the front wall 60 and the bottom wall 64, such that the port cover 78b can close off and cover the port 76b, and such that the port cover 78b can allow a plug to access to the port 76b.

The sealing member 34 includes a rearward portion 80 and a forward portion 82. The rearward portion 80 includes a top wall 84, a bottom wall 86, a first side wall 88, and a second side wall 90. The walls 84, 86, 88, 90 define front and rear faces 92, 94 of the rearward portion 80 and an opening 96 which extends through the rearward portion 80. The forward portion 82 includes a front wall 98, a top wall 100, a bottom wall 102, a first side wall 104, and a second side wall 106. The walls 100, 102, 104, 106 extend rearward from the front wall 98 in a generally perpendicular manner to the front face 92 of the rearward portion 80. The walls 98, 100, 102, 104, 106 also define an open cavity 108 therebetween. The opening 96 and the open cavity 108 are in communication with one another and collectively define an open cavity 109 of the sealing member 34. The top wall 100 further includes an aperture 110 provided therethrough which is in communication with the open cavity 109. The front wall 98 further includes a pair of ports 112a, 112b extending forwardly therefrom and which are in communication with the open cavity 109. Port 112a is positioned above port 112b.

In order to form the housing 22, the sealing member 34 is positioned and secured inside the open cavity 72 of the cover 32. In this position, the front wall 98 of the sealing member 34 is positioned against a rear surface of the front wall 60 of the cover 32, and the ports 112a, 112b of the sealing member 34 are positioned within the ports 76a, 76b of the cover 32, respectively. Further, the top wall 100 of the sealing member 34 is positioned against a lower surface of the top wall 62 of the cover 32 such that the aperture 110 of the sealing member 34 is in communication with the aperture 74 of the cover 32. Still further, the bottom wall 102 of the sealing member 34 is positioned against a top surface of the bottom wall 64 of the cover 32, the first side wall 104 of the sealing member 34 is positioned against an inner surface of the first side wall 66 of the cover 32, and the second side wall 106 of the sealing member 34 is positioned against an inner surface of the second side wall 68 of the cover 32. Still further, the front face 92 of the sealing member 34 is positioned against the rear face 70 of the cover 32 and the outer surfaces of the walls 84, 86, 88, 90 of the sealing member 34 are generally flush with the outer surfaces of the walls 62, 64, 66, 68 of the cover 32, respectively. The front face 50 of the junction box 30 is positioned against the rear face 94 of the sealing member 34 and the outer surfaces of the walls 84, 86, 88, 90 of the sealing member 34 are generally flush with the outer surfaces of the walls 42, 44, 46, 48 of the junction box 30, respectively. The junction box 30, cover 32, and sealing member 34 can be secured together by any desired means, such as, for instance, by a plurality of screws. With the housing 22 thus formed, the open cavities 52, 109 of the junction box 30 and the sealing member 34, respectively, collectively form the cavity 36 of the housing 22.

As also illustrated in FIG. 3 the GFCI receptacle 24 is generally housed within the cavity 36 of the housing 22. The GFCI receptacle includes a ground plate assembly 114 and an electronic circuitry assembly 116.

The ground plate assembly 114 includes a ground plate 118 and a pair of connection inserts 120a, 120b. The connection inserts 120a, 120b are configured to be coupled to a standard three pronged polarized plug. The ground plate 118 has a front face 122, a rear face 124, and a pair of apertures 126a, 126b which extend therethrough from the front face 122 to the rear face 124. The aperture 126a is positioned above aperture 126b. The connection insert 120a is positioned within the aperture 126a and is secured to the ground plate 118. The connection insert 120b is positioned within the aperture 126b and is secured to the ground plate 118. The connection inserts 120a, 120b generally extend rearwardly from the rear face 124 of the ground plate 118, but may also slightly extend forwardly from the front face 122.

The electronic circuit assembly 116 includes a pair of circuit boards 128a, 128b, a wire bundle 130, and other electronic circuitry including, but not limited to, a sensing circuit (not shown), a trip switch (not shown), and first and second connection portions (not shown), all of which are electrically connected to one another. The circuit boards 128a, 128b are preferably arranged in a perpendicular orientation. The wire bundle 130 is releasably electrically connected at a first end (not shown) thereof to one or both of the circuit boards 128a, 128b. A second end (not shown) of the wire bundle 130 is electrically connected to the user interface assembly 28, as will be discussed in further detail hereinbelow. The first connection portion (not shown) is configured to be electrically coupled to the connection insert 120a and the second connection portion (not shown) is configured to be electrically coupled to the connection insert 120b.

The GFCI receptacle 24 is preferably positioned within the cavity 36 of the housing 22 when the front face 122 of the ground plate 118 is positioned against a rear surface of the front wall 98 of the sealing member 34, such that the apertures 126a, 126b of the ground plate 118 are in alignment with and in communication with, the ports 112a, 112b, respectively, of the sealing member 34. If portions of the connection inserts 120a, 120b extend forwardly from the front face 122 of the ground plate 118, these forward portions of the connection inserts 120a, 120b can be positioned within the ports 112a, 112b, respectively, of the sealing member 34. Thus, forward portions of the connection inserts 120a, 120b are configured as receiving portions, accessible through the ports 76a/112a, 76b/112b, respectively, of the cover 32 and the sealing member 34, which are adapted to receive a plug therein. The ports 112a, 112b of the sealing member 34 also provide a seal between the ports 76a, 76b and a mating plug upon connection.

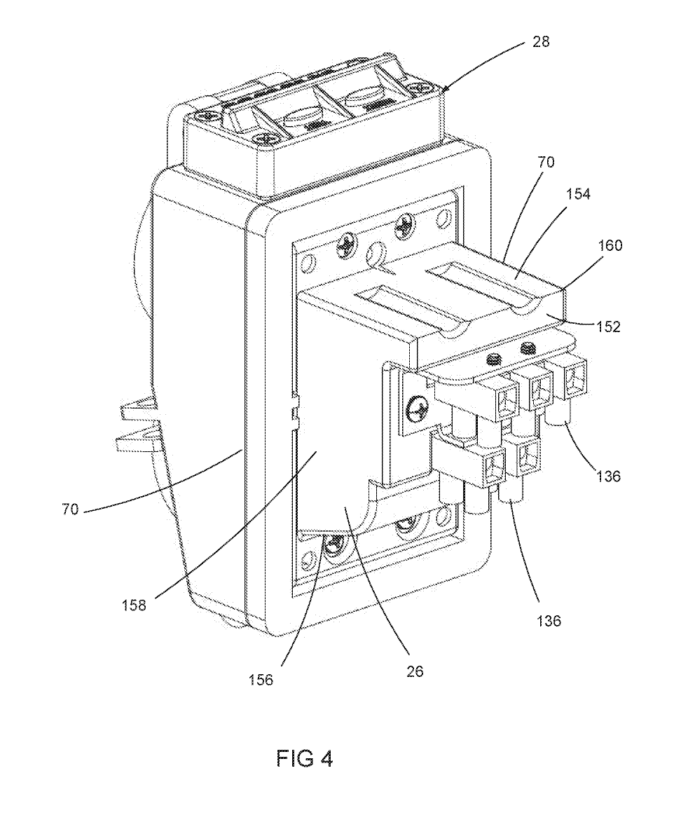

As shown in FIGS. 3-4 the wire cover 26 is generally housed within the cavity 36 of the housing 22. The wire cover 26 includes a forward portion 132, a rearward portion 134, and terminal mounts 136. The forward portion 132 includes a top wall 138, a bottom wall 140, a first side wall 142, and a second side wall 144. The walls 138, 140, 142, 144 define front and rear faces 146, 148 of the forward portion 132 and an opening 150 which extends through the forward portion 132. The rearward portion 134 includes a rear wall 152, a top wall 154, a bottom wall 156, a first side wall 158, and a second side wall 160. The walls 154, 156, 158, 160 extend forward from the rear wall 152 to the rear face 148 of the forward portion 132. The walls 152, 154, 156, 158, 160 also define an open cavity 164 therebetween. The opening 150 and the open cavity 164 are in communication with one another and collectively define an open cavity 166 of the wire cover 26. The terminal mounts 136 are generally associated with one or both of the rear and bottom walls 152, 156. The terminal mounts 136 are configured to be electrically connected to the electronic circuit assembly 116 of the GFCI receptacle 24 and provide wire securing lugs. Wires of the power distribution system are configured to extend into the cavity 36 of the housing 22 via the conduit 54 and are secured to the terminal mounts 136 by the wire securing lugs. The front face 146 of the wire cover 26 is configured to be positioned against either the rear face 124 of the ground plate 118 or the rear surface of the front wall 98 of the sealing member 34. The wire cover 26, cover 32, and sealing member 34 can be secured together by any desired means, such as, for instance, by a plurality of screws.

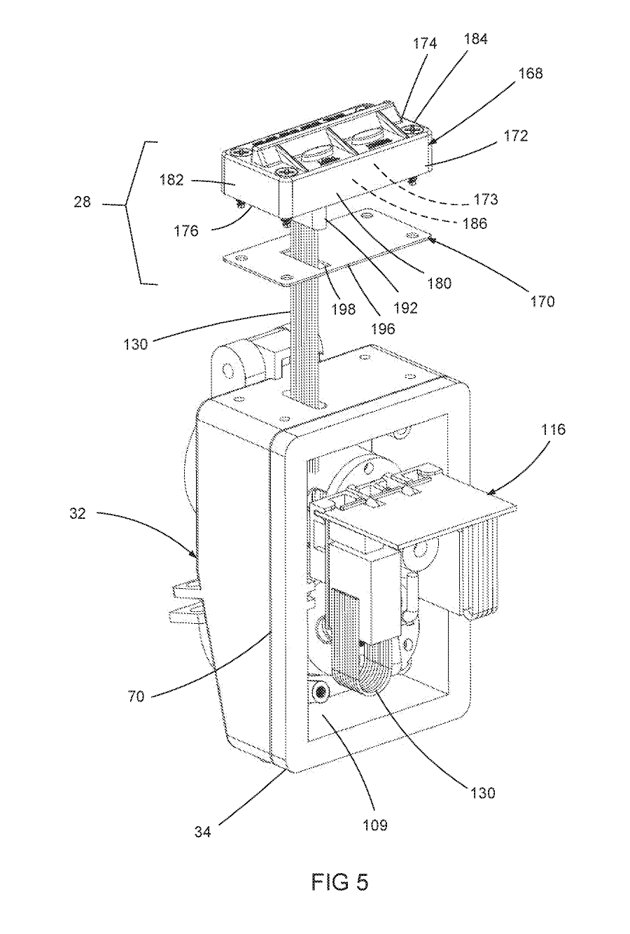

As best shown in FIGS. 4-6 the user interface assembly 28 is positioned outside of the housing 22. The user interface assembly 28 is preferably secured to the housing 22 as described and illustrated hereinbelow, however, it is to be understood that the user interface assembly 28 could also be provided at a location remote from the housing 22 if desired. The user interface assembly 28 includes a user interface 168 and a sealing member 170.

The user interface 168 includes a housing 172 and electronic circuitry 173 which is housed within the housing 172. The housing 172 includes a top wall 174, a bottom wall 176, a front wall 178, a rear wall 180, a first side wall 182, and a second side wall 184, which collectively define a cavity 186 of the housing 172. The electronic circuitry 173 is positioned within the cavity 186. The top wall 174 of the housing 172 includes one or more openings 188 therethrough which allow for one or more portions of the electronic circuitry 173 within the housing 172 to be viewed. The top wall 174 of the housing 172 further includes one or more indices 190 which provide information regarding the one or more portions of the electronic circuitry 173 which are visible. The bottom wall 176 of the housing 172 includes an extension 192 that extends downwardly therefrom. The extension 192 is hollow and thus provides communication to the cavity 186 of the housing 172.

The sealing member 170 is a generally flat member which has a top surface 194, a bottom surface 196, and an aperture 198 which extends therethrough from the top surface 194 to the bottom surface 196.

The user interface assembly 28 is preferably positioned on the top wall 62 of the cover 32 of the housing 22. The bottom surface 196 of the sealing member 170 is positioned against an outer surface of the top wall 62 of the cover 32 of the housing 22 such that the aperture 198 is in general alignment with and in communication with the aperture 74 of the housing 22. The bottom wall 176 of the housing 172 of the user interface 168 is positioned on the top surface 194 of the sealing member 170 and the extension 192 of the user interface 168 extends into the aperture 198 of the sealing member 170. The extension 192 of the user interface 168 may also extend into one or both of the apertures 74, 110 of the cover 32 and sealing member 34, respectively, of the housing 22.

The second end (not shown) of the wire bundle 130 is routed through the cavity 36 of the housing 22 as desired and extends into the cavity 186 of the housing 172 of the user interface 168 to be electrically connected to the electronic circuitry 173 housed therein. The wire bundle 130 thus extends through one or more of the hollow extension 192 of the housing 172 of the user interface 168, the aperture 198 of the sealing member 170, the aperture 74 of the cover 32, and the aperture 110 of the sealing member 34, depending on where the hollow extension 192 terminates.

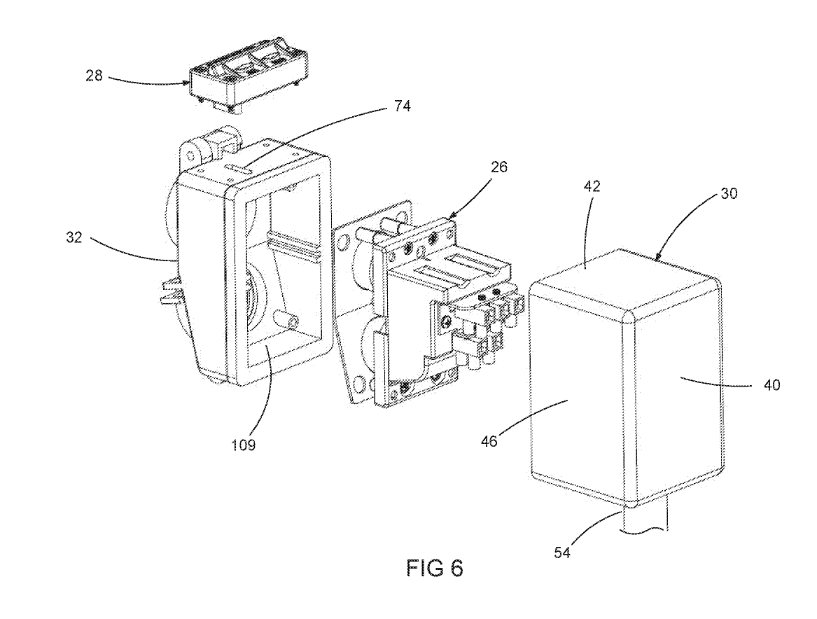

As illustrated in FIG. 6 the GFCI receptacle assembly 20 is configured to be a part of a building wiring system (now shown) which are connected to other GFCI receptacle assemblies throughout a building by conduit 54 with the wire conductors distributed within the conduit 54. The wires of the power distribution system enter the GFCI receptacle assembly 20 and are secured to the terminal mounts 136 and electrically connected to the GFCI receptacle 24. In a typical arrangement, the conduit system is also connected to earth. In this arrangement, a typical connection to a GFCI receptacle 24 includes a hot wire, a neutral wire, and a ground wire, where the ground wire is connected to the GFCI receptacle 24 via a jumper.

While the user interface assembly 28 is described and illustrated as being secured to the top wall 62 of the cover 32 of the housing 22, it is to be understood that, through minor modification, the user interface assembly 28 could alternatively be secured to other walls of the cover 32 or junction box 30 of the housing 22. In a further alternative, through minor modification, the user interface assembly 28 could alternatively not be secured to the housing 22, and instead be positioned remotely from the housing 22.

It is to be understood that the sealing members 34, 170 described herein are intended to be water resistant seals, thereby causing the GFCI receptacle assembly 20 to be water resistant, thereby inhibiting the entrance of moisture or debris into the GFCI receptacle assembly 20.

The electrical connection provided between the user interface assembly 28 and the GFCI receptacle 24 allows for the remote operation of the circuit interrupter. The user interface assembly 28 further includes a test control and a reset control used to operate the GFCI receptacle 24. The GFCI receptacle 24 is also configured to perform a series of tests to ensure that the GFCI receptacle 24 is connected properly. The openings 188 (in connection with the electronic circuitry 173 visible therethrough) and indices 190 of the top wall 174 of the user interface 168, provide visual feedback to the mode and type of failure which may have occurred in operation causing the GFCI receptacle 24 to fail or trip during a fault or any miswiring that occurred during assembly. These tests include, but are not limited to, reverse polarity, open-ground, open-neutral, open-hot, hot-and-ground-reversed, hot-on-neutral, hot-unwired, Ground Fault Circuit Interrupter (GFCI) functional and receptacle tension.

It should be noted that in general, sealed plug and receptacle connectors for residential and business structures are provided with some degree of resistance to moisture and debris infiltration, a self-contained totally sealed system with GFCI capability is not typically available. Generally weather proof receptacles are sealed on the exterior only and once a plug is inserted into a socket, this connection is not sealed. A cover generally seals the exterior of the socket prior to connection and provided with a rotatable cover. In particular, GFCI receptacles which have associated reset and testing circuitry buttons located on the receptacle surface a completely sealed system has not been provided. By removing the testing and reset circuitry away from the receptacle face, the embodiment shows a completely sealed system. Additionally, this also provides the advantage of a remote user interface that is easily accessible to the user. The remote user interface also allows the incorporation of a feedback circuit to indicate the connection status and miswiring detection of the receptacle, which in the past was accomplished by a separate plug-in type tester.

It will be understood that there are numerous modifications of the illustrated embodiments described above which will be readily apparent to one skilled in the art, such as many variations and modifications of the compression connector assembly and/or its components including combinations of features disclosed herein that are individually disclosed or claimed herein, explicitly including additional combinations of such features, or alternatively other types of contact array connectors. Also, there are many possible variations in the materials and configurations.

We claim:

1. A GFCI receptacle assembly:
a housing defining a cavity therein, the housing having a front wall, the front wall having a port extending therefrom which is in communication with the cavity, the port being configured to receive a plug therein;
a GFCI receptacle, the GFCI receptacle is positioned in the cavity of the housing, the GFCI receptacle including a ground plate assembly and an electronic circuit assembly, the ground plate assembly being in communication with the port, the ground plate assembly being configured to electrically connect with the plug to be received in the port, the electronic circuit assembly being electrically connected to the ground plate assembly; and
a user interface assembly, the user interface assembly being electrically connected to the electronic circuit assembly to operationally control the GFCI receptacle, the user interface assembly not being operatively associated with the front wall of the housing.

2. The GFCI receptacle assembly of claim 1, wherein the housing is formed from a junction box and a cover, the front wall of the housing being defined by the cover the second housing is mounted on the housing.

3. The GFCI receptacle assembly of claim 2, wherein the housing further includes a sealing member positioned between the junction box and the cover.

4. The GFCI receptacle assembly of claim 3, wherein the sealing member includes a forward portion and a rearward portion, the rearward portion of the sealing member being positioned between the junction box and the cover, the forward portion of the sealing member being positioned against an inner surface of the cover, the forward portion of the sealing member having a port, the port of the forward portion of the sealing member being positioned within the port of the cover.

5. The GFCI receptacle assembly of claim 2, wherein the cover has a top wall, and the user interface assembly is mounted on the top wall.

6. The GFCI receptacle assembly of claim 5, the user interface assembly includes a housing, electronic circuitry positioned in the housing, and a sealing member, the sealing member being positioned between the top wall of the cover and the housing, the electronic circuitry extending through the housing and the sealing member of the user interface assembly and being electrically connected to the electronic circuit assembly to operationally control the GFCI receptacle.

7. The GFCI receptacle assembly of claim 6, wherein the electronic circuit assembly of the GFCI receptacle includes a wire bundle having first and second ends, the first end of the wire bundle being electrically connected to the ground plate assembly, the second end of the wire bundle being electrically connected to the electronic circuitry of the user interface assembly.

8. The GFCI receptacle assembly of claim 1, wherein the housing has a plurality of walls including the front wall, and wherein the user interface assembly is mounted to any of the plurality of walls of the housing other than the front wall.

9. The GFCI receptacle assembly of claim 1, wherein the user interface assembly is positioned remotely from the housing.

10. The GFCI receptacle assembly of claim 1, wherein further comprising a wire cover having a terminal block, the wire cover being positioned within the cavity of the housing, the terminal block being electrically connected to the electronic circuit assembly.

11. The GFCI receptacle assembly of claim 1, wherein the electronic circuit assembly of the GFCI receptacle includes fault detecting circuitry and a control board.

12. A water-resistant GFCI receptacle assembly comprising:
a first housing defining a cavity therein, the first housing having a first wall and a second wall, the first wall having a port extending therefrom which is in communication with the cavity, the port being configured to receive a plug therein;
a GFCI receptacle, the GFCI receptacle is positioned in the cavity of the first housing, the GFCI receptacle including a ground plate assembly and an electronic circuit assembly, the ground plate assembly being in communication with the port of the cover, the ground plate assembly being configured to electrically connect with the plug received in the port of the cover, the electronic circuit assembly being electrically connected to the ground plate assembly, the electronic circuit assembly including a circuit board and a wire bundle having first and second ends, the first end of the wire bundle being electrically connected to the circuit board; and
a user interface assembly, the user interface assembly including
a second housing,
electronic circuitry, the electronic circuitry being positioned in the second housing,
a first sealing member, the first sealing member being positioned between the second housing and the second wall of the first housing,
wherein the wire bundle extends through the second wall and the first sealing member, with the second end of the wire bundle being electrically connected to the electronic circuitry of the user interface assembly, whereby the user interface assembly is electrically connected to the electronic circuit assembly to operationally control the GFCI receptacle.

13. The water-resistant GFCI receptacle assembly of claim 12, wherein the housing includes a junction box, a cover and a second sealing member which provides a seal between the junction box and the cover.

14. The water-resistant GFCI receptacle assembly of claim 13, wherein the first wall of the first housing is defined by a front wall of the cover, and wherein the second wall of the first housing is defined by a top wall of the cover.

15. The water-resistant GFCI receptacle assembly of claim 14, wherein the junction box defines a forward face, wherein the cover defines a rear face and an inner surface, and wherein the second sealing member includes a forward portion and a rearward portion, the rearward portion of the second sealing member being positioned between the forward face of the junction box and the rear face of the cover to provide the seal therebetween, the forward portion of the second sealing member being positioned against the inner surface of the cover, the forward portion of the second sealing member having a port, the port of the forward portion of the second sealing member being positioned within the port of the cover.

16. The water-resistant GFCI receptacle assembly of claim 12, further comprising a wire cover having a terminal block, the wire cover being positioned within the cavity of the first housing, the terminal block being electrically connected to the electronic circuit assembly.

17. The water-resistant GFCI receptacle assembly of claim 12, wherein the electronic circuit assembly of the GFCI receptacle further includes fault detecting circuitry.

18. A GFCI receptacle, comprising:
a ground plate, a connection insert secured to the ground plate, the ground plate and the connection insert electrically connected to an electrical assembly, the electrical assembly includes fault detecting circuitry and a receptacle control board, the electrical assembly mounted to the ground plate, and a user interface including a circuit assembly, the circuit assembly is electrically connected to the electrical assembly; and wherein the user interface is separate from the ground plate.

19. The GFCI receptacle of claim 18, wherein a wire bundle connects the circuit assembly to the electrical assembly.

20. The GFCI receptacle of claim 19, wherein the GFCI is disposed in a housing and the user interface is mounted on the exterior of the housing.
